(19) United States
(12) Patent Application Publication
(10) Pub. No.: US 2025/0046677 A1
(43) Pub. Date: Feb. 6, 2025

(54) SEMICONDUCTOR STRUCTURE AND METHOD OF MANUFACTURE

(71) Applicant: Taiwan Semiconductor Manufacturing Company Limited, Hsin-Chu (TW)

(72) Inventors: Shih-Yu LIAO, Hsinchu City (TW); Chung-Liang Cheng, Changhua County (TW)

(21) Appl. No.: 18/228,352

(22) Filed: Jul. 31, 2023

(51) Int. Cl. H01L 23/48; H01L 29/06; H01L 29/423; H01L 29/66; H01L 29/775; H01L 29/78; H01L 29/786; H10B 12/00; H10B 51/30; H10B 61/00; H10B 63/00

(52) U.S. Cl. CPC H01L 23/481; H01L 29/0673; H01L 29/42392; H01L 29/66439; H01L 29/66795; H01L 29/775; H01L 29/7851; H01L 29/7869; H01L 29/78696; H10B 12/36; H10B 51/30; H10B 61/22; H10B 63/34

(57) ABSTRACT

A semiconductor structure and method for forming the semiconductor are provided. The semiconductor structure includes a logic device, a first contact connected to the logic device, a first power rail over the logic device and connected to the logic device, and a second power rail over the logic device. A transistor having a channel region including indium, gallium, zinc, and oxygen is over the second power rail and connected to the second power rail.

### BACKGROUND

As the semiconductor industry has progressed into nanometer technology process nodes in pursuit of higher device density, higher performance, and lower costs, challenges from both fabrication and design issues have resulted in the development of three dimensional designs, such as gate-all-around (GAA) transistors. A GAA transistor comprises one or more nano-sheet or nano-wire channel regions having a gate wrapped around the nano-sheet or nano-wire. GAA transistors can reduce the short channel effect.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-11 are illustrations of a semiconductor structure at various stages of fabrication, in accordance with some embodiments.

FIGS. 12-16 are illustrations of a semiconductor structure at various stages of fabrication, in accordance with some embodiments.

FIGS. 17-20 are illustrations of a semiconductor structure at various stages of fabrication, in accordance with some embodiments.

FIGS. 21-26 are illustrations of a semiconductor structure at various stages of fabrication, in accordance with some embodiments.

FIGS. 27-30 are illustrations of a semiconductor structure at various stages of fabrication, in accordance with some embodiments.

FIGS. 31-32 are illustrations of a semiconductor structure at various stages of fabrication, in accordance with some embodiments.

### DETAILED DESCRIPTION

The following disclosure provides many different embodiments, or examples, for implementing different features of the provided subject matter. Specific examples of components and structures are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below.” “lower.” “above,” “upper”, and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The apparatus may be otherwise oriented (rotated 90 degrees or at other orientations) and the spatially relative descriptors used herein may likewise be interpreted accordingly.

One or more techniques for fabricating a semiconductor structure are provided herein. In some embodiments, the semiconductor structure comprises a nano-structure transistor and a nano-structure memory structure. As used herein, nano-structure devices, such as a nano-structure transistor or a nano-structure memory structure, refer to substantially flat, nearly two-dimensional structures, such as sometimes referred to as nano-sheets, as well as structures having two-dimensions that are similar in magnitude, such as sometimes referred to as nano-wires. Nano-sheet devices may have rectangular cross-sections and nano-wire devices may have elliptical cross-sections.

In some embodiments, a semiconductor wafer with the logic devices formed thereon, referred to as a device wafer, is inverted and bonded on its top side to a carrier wafer. Memory devices are formed in layers over the backside of the device wafer using a low thermal budget back end of line (BEOL) process. A first buried power rail connects to the logic devices and a second buried power rail connects to the memory devices. The memory devices may be three-dimensional (3D) memory devices such as resistive random access memory (RRAM) devices, dynamic random access memory (DRAM) devices, magnetic random access memory (MRAM) devices, ferromagnetic random access memory (FeRAM) devices, or some other memory technology. In some embodiments, additional memory devices, such as metal-insulator-metal (MIM) devices are formed on the carrier wafer under the logic devices.

The device wafer may be bonded to the carrier wafer using a hybrid bonding process, where conductive structures embedded in a dielectric layer of the device wafer align with conductive structures embedded in a dielectric layer on the carrier wafer to form interconnections. In a hybrid bonding process, heat and/or pressure is applied to cause the conductive structures in the device wafer to bond with the conductive structures in the carrier wafer and to cause the dielectric layer of the device wafer to bond with the dielectric layer of the carrier wafer.

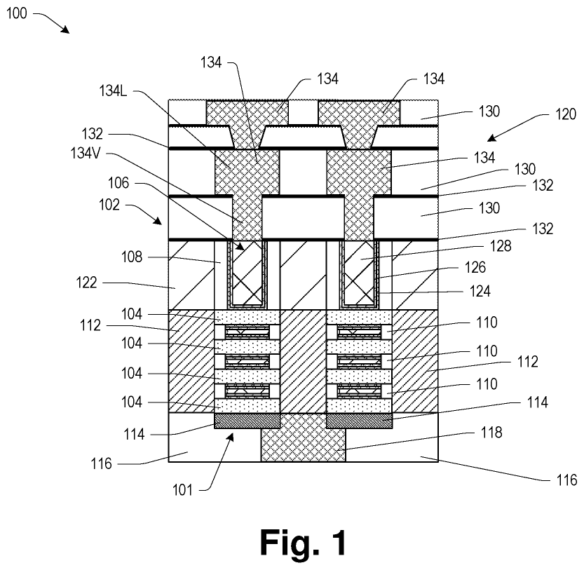

FIGS. 1-11 are illustrations of a semiconductor structure 100 at various stages of fabrication, in accordance with some embodiments. The views of FIGS. 1-11 are cross-sectional views taken through the semiconductor structure 100 in a direction corresponding to a gate width direction through logic devices 101 formed on a device wafer 102. Referring to FIG. 1, the logic devices 101 are nano-structures comprising channel semiconductor layers 104, gate structures 106, sidewall spacers 108, end spacers 110, source/drain regions 112, and bottom dielectric layers 114, in accordance with some embodiments. Isolation structures 116 are formed under the logic devices 101 and a source/drain contact 118 is embedded in the isolation structures 116 and contacts the source/drain regions 112. The source/drain regions 112 may comprise epitaxial silicon doped with an n-type or p-type dopant. The source/drain regions 112 may comprise Ge or C to generate compressive or tensile stress, respectively. The isolation structures 116 may be local oxidation of silicon (LOCOS) structures, shallow trench isolation (STI) structures, or deep trench isolation (DTI) structures. In some embodiments, metallization layers 120 are formed over the logic devices 101. Although the logic devices 101 are illustrated as being nano-structures, other types of logic devices may be provided on the device wafer 102 in addition to or in place of the nano-structures, such as planar devices, fin field-effect transistor (finFET) devices, or some other type of logic devices.

In some embodiments, the logic devices 101 are formed over a semiconductor layer which is later removed, such as by a planarization process. The semiconductor layer is part of a substrate of the device wafer 102 comprising at least one of an epitaxial layer, a single crystalline semiconductor material such as, but not limited to Si, Ge, SiGe, InGaAs, GaAs, InSb, GaP, GaSb, InAlAs, GaSbP, GaAsSb, and InP, a silicon-on-insulator (SOI) structure, a wafer, or a die formed from a wafer. The semiconductor layer may also comprise crystalline silicon. The logic devices 101 may be formed by forming a stack comprising the channel semiconductor layers 104 and sacrificial semiconductor layers. The materials of the channel semiconductor layers 104 may be different than the materials of the sacrificial semiconductor layers to provide etch selectivity and allow removal of the sacrificial semiconductor layers. In some embodiments, the channel semiconductor layers 104 may comprise substantially pure silicon, and the sacrificial semiconductor layers may comprise silicon-germanium (SiₓGe₍₁₋ₓ₎, where x ranges from 0.25 to 0.85). In some embodiments, the number of channel semiconductor layers 104 and the number of sacrificial semiconductor layers may vary. The order of the channel semiconductor layers 104 and the sacrificial semiconductor layers may vary. Thicknesses of the channel semiconductor layers 104 and the sacrificial semiconductor layers may vary, and the thicknesses need not be the same. For example, the thicknesses of the channel semiconductor layers 104 and the sacrificial semiconductor layers may decrease from the bottommost layers to the topmost layers.

In some embodiments, the gate structures 106 are formed by forming sacrificial gate structures and forming the sidewall spacers 108 adjacent the sacrificial gate electrodes. The end spacers 110 are formed adjacent ends of the sacrificial semiconductor layers and the source/drain regions 112. The sidewall spacers 108 may comprise nitrogen and silicon or other suitable materials. The sacrificial gate electrodes may comprise a sacrificial gate dielectric layer, such as silicon dioxide, and a sacrificial gate electrode, such as polysilicon. The isotropic etch process is performed to recess the sacrificial semiconductor layers to define end cavities. A deposition process is performed to form a dielectric spacer layer over the channel semiconductor layers 104, the sacrificial semiconductor layers, and the gate structures 106, and an isotropic etch process is performed to remove portions of the dielectric spacer layer outside the end cavities to define the end spacers 110. The end spacers 110 may comprise a low-k dielectric material, for example, SiON, SiOCN, SiCN, SiOC, or some other suitable material. The end spacers 110 may comprise the same material composition as the sidewall spacers 108.

In some embodiments, the source/drain regions 112 are formed after forming the sacrificial gate structures and the end spacers 110. An epitaxial growth process may be performed to form the source/drain regions 112. The source/drain regions 112 may comprise SiP, SiC, or some other suitable material for an n-type device, or the source/drain regions 112 may comprise SiGe, SiB, or some other suitable material for a p-type device. The source/drain regions 112 may refer to a source or a drain, individually or collectively dependent upon the context.

A dielectric layer 122 is formed adjacent the sidewall spacers 108 and planarized to expose the sacrificial gate structures. The dielectric layer 122 comprises silicon dioxide, a low-k dielectric material, one or more layers of low-k dielectric material, or some other suitable dielectric material. The materials for the dielectric layer 122 comprise at least one of Si, O, C, or H, such as SiCOH and SiOC, or other suitable materials. Organic material such as polymers may be used for the dielectric layer 122. The dielectric layer 122 may comprise one or more layers of a carbon-containing material, organo-silicate glass, a porogen-containing material, or combinations thereof. The dielectric layer 122 may also comprise nitrogen. The dielectric layer 122 may be formed by using, for example, at least one of low pressure chemical vapor deposition (CVD) (LPCVD), atomic layer CVD (ALCVD), or a spin-on technology.

The sacrificial gate structures and the sacrificial semiconductor layers are removed to form a gate cavity, and the gate structures 106 are formed in the gate cavity. The gate cavity comprises intermediate regions between the channel semiconductor layers 104 such that the gate structures 106 surround the channel semiconductor layers 104, an arrangement referred to as a gate all around (GAA) structure. An etch process is performed to remove the sacrificial gate electrode and the sacrificial gate dielectric layer. The etch process may be a wet etch process selective to the material of the sacrificial gate electrode and the material of the sacrificial gate dielectric layer. Another etch process, such as a wet etch process, is performed to remove the sacrificial semiconductor layers to define the gate cavity.

The gate structures 106 are formed in the gate cavity, including the intermediate cavities between the channel semiconductor layers 104. In some embodiments, the gate structures 106 comprise a gate dielectric layer 124, a work function material layer 126, and a gate electrode layer 128. The gate dielectric layer 124 may comprise SiO₂, HfO, La, SiON, SiCON, Zn, Zr, or some other suitable material. The gate dielectric layer 124 may comprise a native oxide layer formed by exposure of the semiconductor structure 100 to oxygen at various points in the process flow, causing the formation of silicon dioxide on exposed surfaces of the channel semiconductor layers 104. An additional layer of dielectric material, such as a high-k dielectric material or other suitable material, is formed over the native oxide to form the gate dielectric layer 124. As used herein, the term “high-k dielectric” refers to the material having a dielectric constant, k, greater than about 3.9, which is the k value of SiO₂. The material of the high-k dielectric layer may be any suitable material. Examples of the material of the high-k dielectric layer include but are not limited to Al₂O₃, HfO₂, ZrO₂, La₂O₃, TiO₂, SrTiO₃, LaAlO₃, Y₂O₃, Al₂OₓN_{y}, HfOₓN_{y}, ZrOₓN_{y}, La₂OₓN_{y}, TiOₓN_{y}, SrTiOₓN_{y}, LaAlOₓN_{y}, Y₂OₓN_{y}, SiON, SiNₓ, SiON, SiCON, ZnO, a silicate thereof, or an alloy thereof. Each value of x is independently from 0.5 to 3, and each value of y is independently from 0 to 2. The work function material layer 126 may comprise TiN, TaN, WN, MON, or some other suitable material for a p-type device, or AlC, TiAlC, TaAlC, TiSi, TaSi, WSi, CoSi, NiSi, or some other suitable material for an n-type device. The gate electrode layer 128 may comprises a metal fill layer, such as W, Ti, Ta, Al, Zn, In, Ga, Ge, C or other suitable material. The gate dielectric layer 124, the work function material layer 126, and/or the gate electrode layer 128, and any other suitable layers of the gate structures 106 may be deposited by at least one of atomic layer deposition (ALD), physical vapor deposition (PVD), CVD, or other suitable processes. According to some embodiments, a planarization process is performed to remove portions of the material forming the gate structure 106 positioned over the dielectric layer 122.

In some embodiments, the metallization layers 120 comprise one or more dielectric layers 130 formed over the dielectric layer 122. Any number of dielectric layers 130 are contemplated. In some embodiments, at least one of the dielectric layers 130 comprises a material with a medium or low dielectric constant, such as SiO₂. The dielectric layers 130 are formed in any number of ways, such as by thermal growth, chemical growth, ALD, CVD, plasma-enhanced (PECVD), and/or other suitable techniques. In some embodiments, the semiconductor structure 100 comprises one or more etch stop layers 132 separating the dielectric layers 130. In some embodiments, the etch stop layers 132 stop an etching process between the dielectric layers 130. According to some embodiments, the etch stop layers 132 comprise a dielectric material having a different etch selectivity from the dielectric layers 130. In some embodiments, at least one of the etch stop layers 132 comprises SiN, SiCN, SiCO, and/or CN. The etch stop layers 132 are formed in any number of ways, such as by thermal growth, chemical growth, ALD, CVD, PECVD, and/or other suitable techniques.

In some embodiments, the metallization layers 120 comprise one or more conductive structures 134 electrically connected to the gate electrode layers 128 or lower conductive structures 134. In an embodiment, the conductive structures 134 extend through the respective dielectric layers 130. In some embodiments, at least some of the conductive structures 134 comprise a via portion 134V and a line portion 134L. The line portions 134L are wider than the via portions 134V and have an axial length extending into the page. In some embodiments, the conductive structures 134 comprise a barrier layer, a seed layer, a metal fill layer, and/or other suitable layers. In some embodiments, the metal fill layer comprises tungsten, aluminum, copper, cobalt, and/or other suitable materials. Other structures and/or configurations of the conductive structures 134 are within the scope of the present disclosure.

In some embodiments, the source/drain contact 118 is formed by inverting the device wafer 102, removing the semiconductor layer that was the substrate of the device wafer 102, forming an opening in the isolation structure 116, and forming the source/drain contact 118 in the opening.

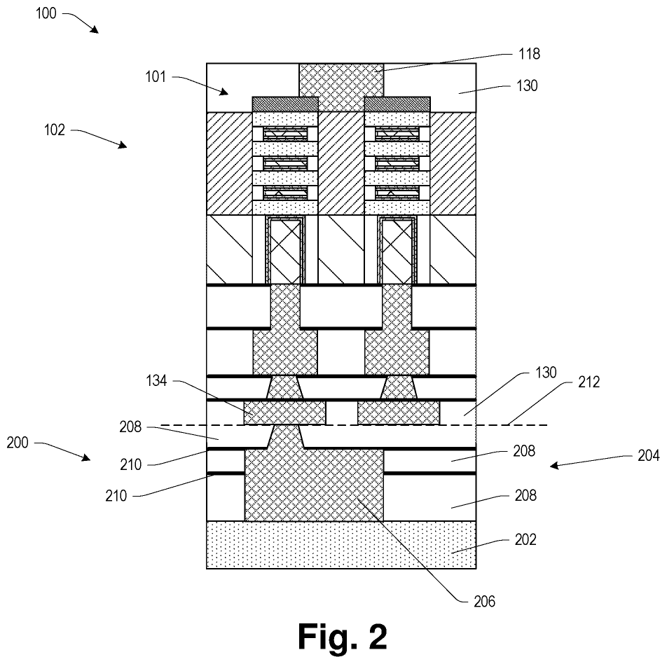

Referring to FIG. 2, the device wafer 102 is inverted and bonded to a carrier wafer 200, in accordance with some embodiments. For case of illustration, not all of the reference numbers on the device wafer 102 are included in FIG. 2. In some embodiments, the carrier wafer 200 comprises a substrate layer 202 and metallization layer 204 over the substrate layer 202. A conductive structure 206 is embedded in dielectric layers 208 of the metallization layer 204. In some embodiments, the conductive structure 206 comprises a barrier layer, a seed layer, a metal fill layer, and/or other suitable layers. In some embodiments, the metal fill layer comprises tungsten, aluminum, copper, cobalt, and/or other suitable materials. Other structures and/or configurations of the conductive structure 206 are within the scope of the present disclosure. In some embodiments, at least one of the dielectric layers 208 comprises a material with a medium or low dielectric constant, such as SiO₂. The dielectric layers 208 are formed in any number of ways, such as by thermal growth, chemical growth, ALD, CVD, PECVD, and/or other suitable techniques. In some embodiments, etch stop layers 210 are formed separating the dielectric layers 208. In some embodiments, the etch stop layers 210 stop an etching process between the dielectric layers 208 when recesses are formed for the conductive structure 206. According to some embodiments, the etch stop layers 210 comprise a dielectric material having a different etch selectivity from the dielectric layers 208. In some embodiments, at least one of the etch stop layers 210 comprises SiN, SiCN, SiCO, and/or CN. The etch stop layers 210 are formed in any number of ways, such as by thermal growth, chemical growth, ALD, CVD, PECVD, and/or other suitable techniques.

In some embodiments, a hybrid bonding process is used to bond the device wafer 102 to the carrier wafer 200 to form a hybrid bond interface 212. In a hybrid bonding process conductive structures embedded in a dielectric layer of the device wafer align and bond with conductive structures embedded in a dielectric layer on the carrier wafer to form interconnections. In a hybrid bonding process, heat and/or pressure is applied to cause the conductive structures in the device wafer to bond with the conductive structures in the carrier wafer and to cause the dielectric layer of the device wafer to bond with the dielectric layer of the carrier wafer. For example, when temperature and/or heat are applied to the device wafer 102 and the carrier wafer 200, similar materials on each semiconductor wafer 102, 200 form hybrid bonds with one another. The embedded conductive structure 206 in the carrier wafer 200 bonds with the conductive structure 134 in the device wafer 102. Other bonds between conductive structures may be present into or out of the page. The exposed dielectric layer 208 of the carrier wafer 200 bonds with the exposed dielectric layer 130 of the device wafer 102. The conductive structure 206 and the conductive structures 134 increase heat transfer between the device wafer 102 and the carrier wafer 200, potentially increasing performance of the semiconductor structure 100.

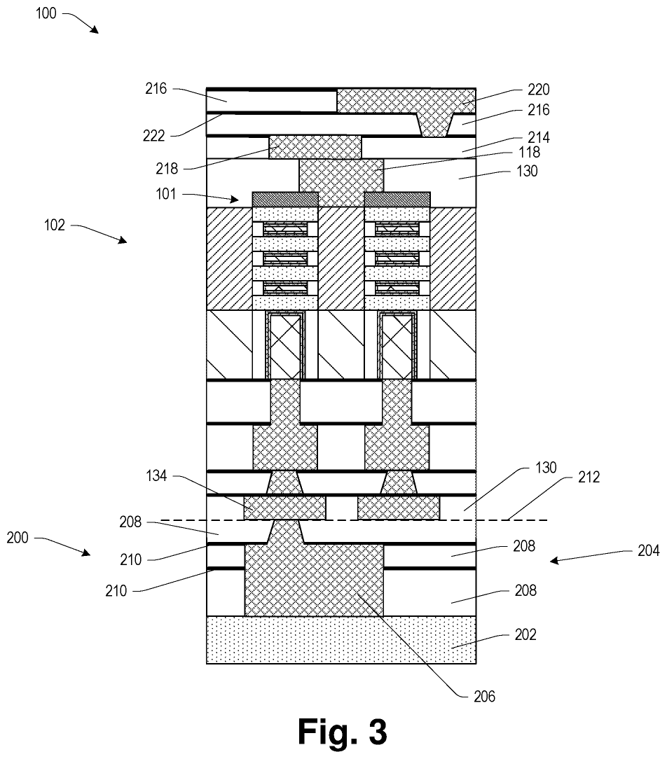

Referring to FIG. 3, dielectric layers 214, 216 are formed over the upper exposed dielectric layer 130 and the source/drain contact 118, and power rails 218, 220 are formed in the dielectric layers 214, 216, respectively, in accordance with some embodiments. The power rail 218 contacts the source/drain contact 118. In some embodiments, the power rail 218 has a smaller width compared to the power rail 220 to support a different supply voltage. For example, the voltage on the power rail 220 may be higher than the voltage on the power rail 218. The dielectric layers 214, 216 may comprise a material with a medium or low dielectric constant, such as SiO₂. The dielectric layers 214, 216 are formed in any number of ways, such as by thermal growth, chemical growth, ALD, CVD, PECVD, and/or other suitable techniques. In some embodiments, a trench is formed in the dielectric layer 214 and the trench is filled with a conductive material and planarized to form the power rail 218. The dielectric layer 216 is formed over the power rail 218 and the dielectric layer 214. A trench and a via opening are formed in the dielectric layer 216, for example, using a dual damascene process and an etch stop layer 222, and the trench and the via opening are filled with a conductive material and planarized. In some embodiments, the power rails 218, 220 comprise a barrier layer, a seed layer, a metal fill layer, and/or other suitable layers. In some embodiments, the metal fill layer comprises W, Ru, Ir, and/or other suitable materials. Other structures and/or configurations of the power rails 218, 220 are within the scope of the present disclosure.

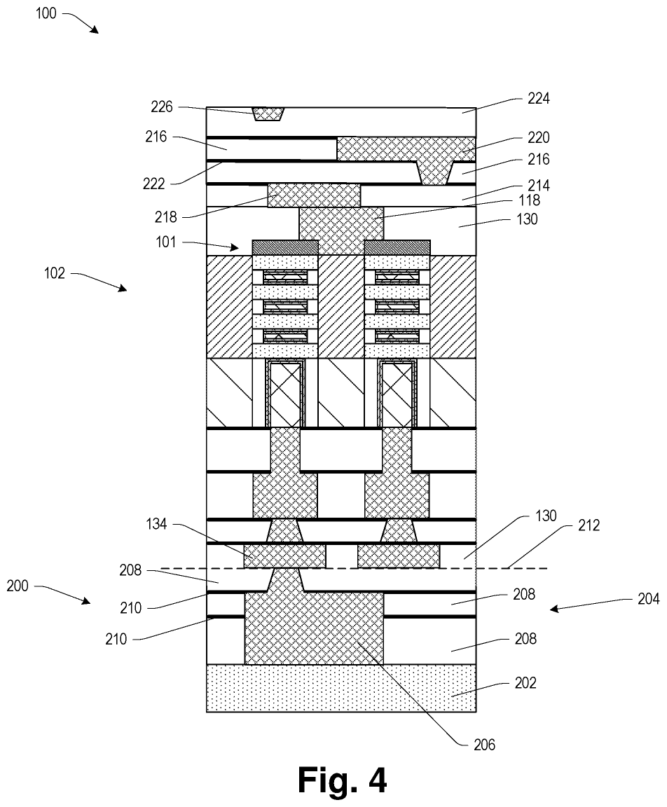

Referring to FIG. 4, a dielectric layer 224 is formed over the power rail 220 and the dielectric layer 216, and a gate contact 226 is formed in the dielectric layer 224, in accordance with some embodiments. The dielectric layer 224 may comprise a material with a medium or low dielectric constant, such as SiO₂. The dielectric layer 224 is formed in any number of ways, such as by thermal growth, chemical growth, ALD, CVD, PECVD, and/or other suitable techniques. In some embodiments, a trench is formed in the dielectric layer 224 and the trench is filled with a conductive material and planarized to form the gate contact 226. In some embodiments, the gate contact 226 comprises a barrier layer, a seed layer, a metal fill layer, and/or other suitable layers. In some embodiments, the metal fill layer comprises tungsten, aluminum, copper, cobalt, and/or other suitable materials.

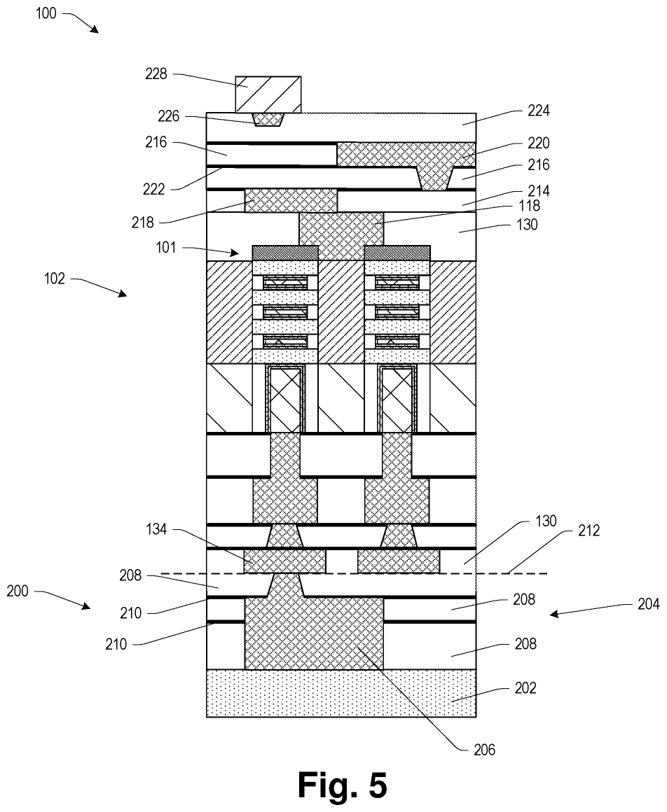

Referring to FIG. 5, a gate electrode 228 is formed over the dielectric layer 224 and the gate contact 226, in accordance with some embodiments. In some embodiments, the gate electrode 228 is formed by depositing a layer of gate electrode material and performing a patterned etch process to form a fin. In some embodiments, the gate electrode 228 comprises titanium nitride.

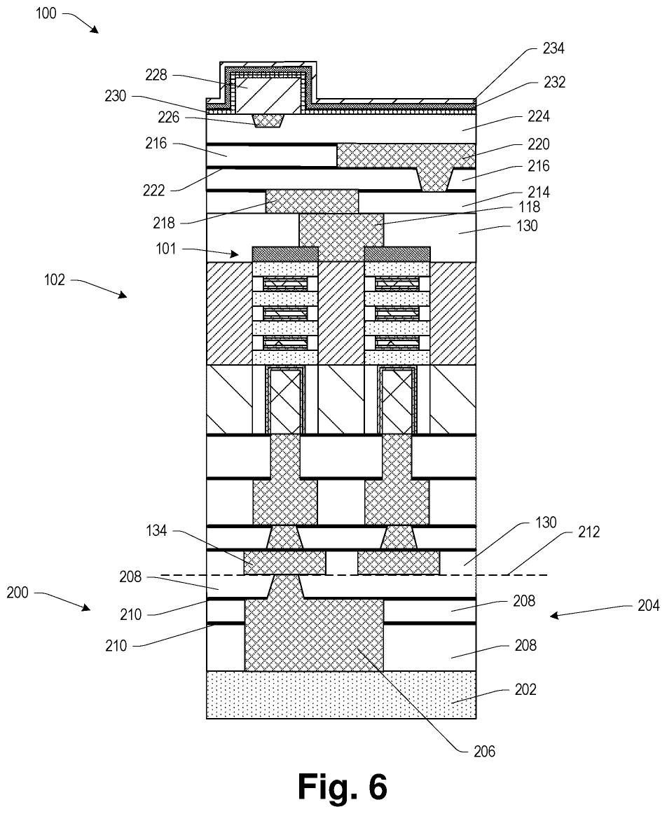

Referring to FIG. 6, a gate dielectric layer 230, a channel layer 232, and a contact layer 234 are formed over the gate electrode 228, in accordance with some embodiments. The gate dielectric layer 230 may comprise a high-k dielectric material. In some embodiments, the channel layer 232 comprises amorphous indium gallium zinc oxide (IGZO). The contact layer 234 may comprise the same material as the gate electrode 228, such as titanium nitride.

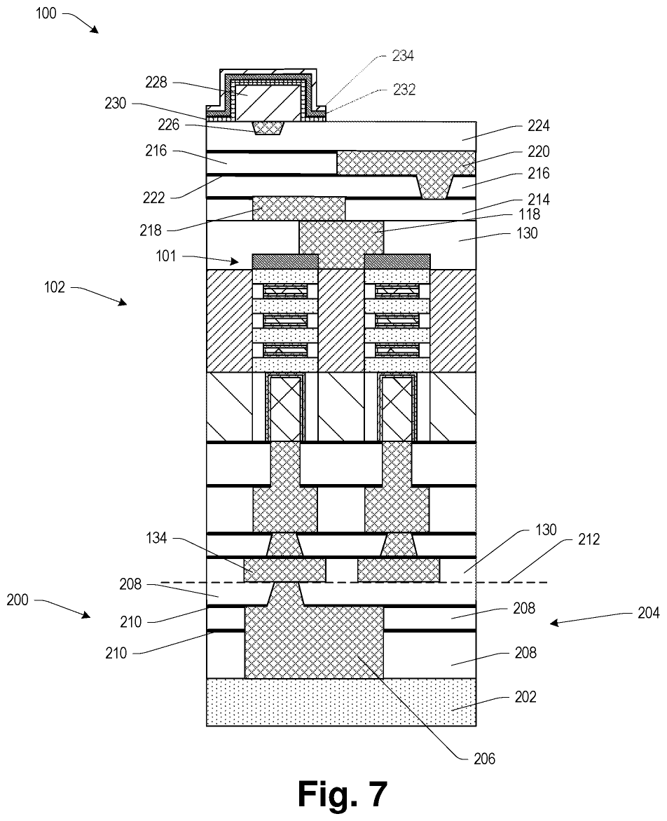

Referring to FIG. 7, the gate dielectric layer 230, the channel layer 232, and the contact layer 234 are patterned, in accordance with some embodiments. The gate dielectric layer 230, the channel layer 232, and the contact layer 234 may be patterned by performing an etch process in the presence of a patterned etch mask.

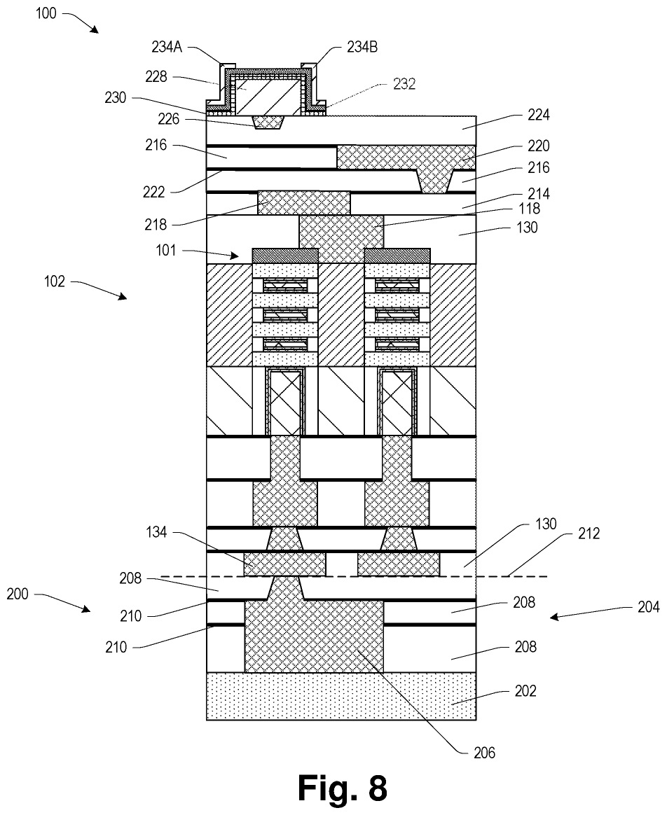

Referring to FIG. 8, the contact layer 234 is patterned to form source/drain contacts 234A, 234B, in accordance with some embodiments. The contact layer 234 may be patterned by performing an etch process in the presence of a patterned etch mask. In some embodiments, the gate electrode 228, the gate dielectric layer 230, the channel layer 232, and the source/drain contacts 234A, 234B define a thin film transistor (TFT) 236. In some embodiments, the gate electrode 228 comprises a fin structure, and the TFT 236 is a bottom gate finFET.

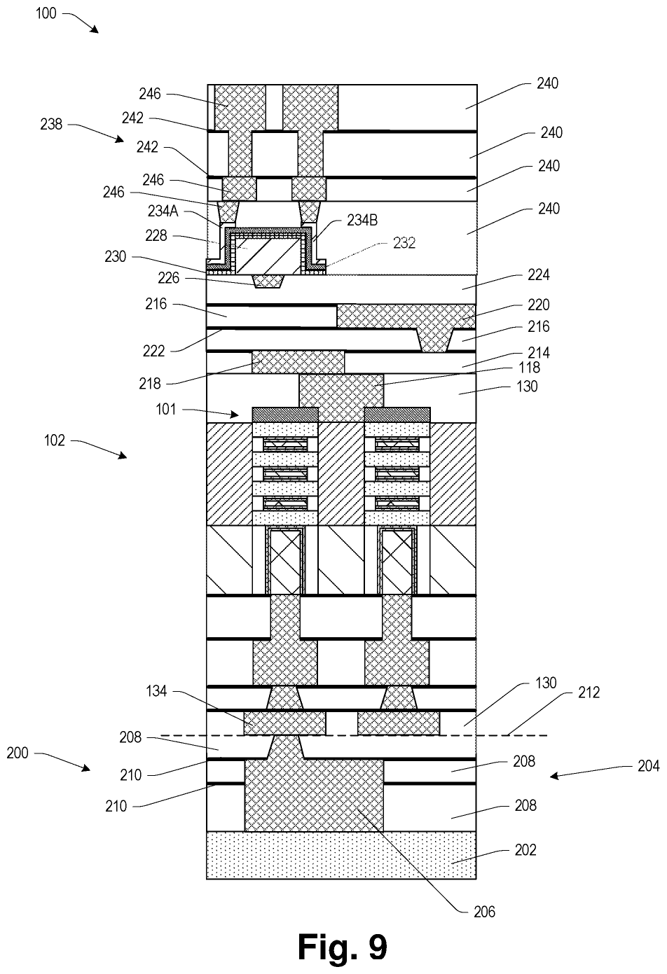

Referring to FIG. 9, metallization layers 238 are formed over the TFT 236, in accordance with some embodiments. In some embodiments, the metallization layers 238 comprise one or more dielectric layers 240 formed over the TFT 236. Any number of dielectric layers 240 are contemplated. In some embodiments, at least one of the dielectric layers 240 comprises a material with a medium or low dielectric constant, such as SiO₂. The dielectric layers 240 are formed in any number of ways, such as by thermal growth, chemical growth, ALD, CVD, PECVD, and/or other suitable techniques. In some embodiments, the semiconductor structure 100 comprises one or more etch stop layers 242 separating the dielectric layers 240. In some embodiments, the etch stop layers 242 stop an etching process between the dielectric layers 240. According to some embodiments, the etch stop layers 242 comprise a dielectric material having a different etch selectivity from the dielectric layers 240. In some embodiments, at least one of the etch stop layers 242 comprises SiN, SiCN, SiCO, and/or CN. The etch stop layers 242 are formed in any number of ways, such as by thermal growth, chemical growth, ALD, CVD, PECVD, and/or other suitable techniques.

In some embodiments, the metallization layers 238 comprise one or more conductive structures 246 electrically connected to the source/drain contacts 234A, 234B. In an embodiment, the conductive structures 246 extend through the respective dielectric layers 130. In some embodiments, at least some of the conductive structures 246 comprise a via portion and a line portion. The line portions are wider than the via portions and have an axial length extending into the page. In some embodiments, the conductive structures 246 comprise a barrier layer, a seed layer, a metal fill layer, and/or other suitable layers. In some embodiments, the metal fill layer comprises tungsten, aluminum, copper, cobalt, and/or other suitable materials. Other structures and/or configurations of the conductive structures 246 are within the scope of the present disclosure.

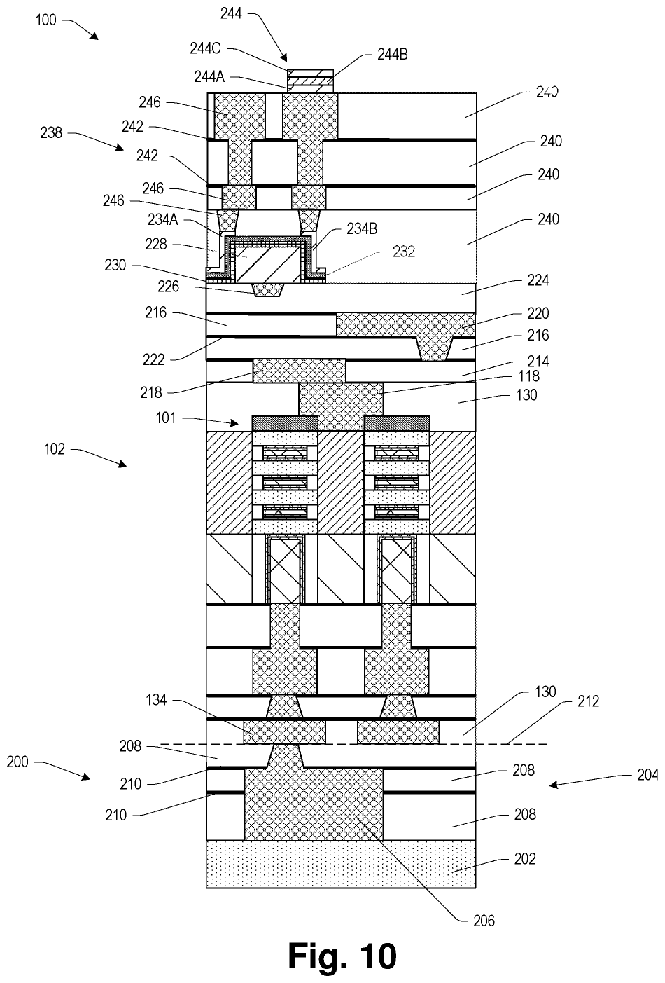

Referring to FIG. 10, a storage element 244 is formed over the metallization layers 238 and connected to the source/drain contact 234B by the conductive structures 246, in accordance with some embodiments. In some embodiments, the storage element 244 is formed by depositing a first layer 244A, a second layer 244B over the first layer 244A, and a third layer 244C over the second layer 244B and performing an etch process in the presence of a patterned etch mask to define the storage element 244. The storage element 244 may comprise a metal-insulator-metal (MIM) storage element. In some embodiments, the storage element 244 may comprise additional layers. For a DRAM storage element, the first layer 244A and the third layer 244C may comprise conductive materials, such as TiN or Ti, and the second layer 244B may be an insulator layer, such as HfO₂ or a different high-k material. For an RRAM storage element, the first layer 244A and the third layer 244C may comprise conductive materials, such as TiN or Ti, and the second layer 244B may be an insulator layer that acts as a resistor, such as HfO₂ or a different high-k material. For an MRAM storage element, the first layer 244A may comprise a pinned layer having a ferromagnetic material, such as a cobalt-iron film (CoFe), a cobalt-iron-boron (CoFeB) film, or other suitable ferromagnetic materials. The second layer 244B may comprise a tunnel barrier layer (insulator layer), such as MgO. The third layer 244C may comprise a free layer having a ferromagnetic material, such as a cobalt-iron film (CoFe), a cobalt-iron-boron (CoFeB) film, or other suitable ferromagnetic materials. For a FeRAM storage element, the first layer 244A and the third layer 244C may comprise conductive materials, such as TiN or Ti, and the second layer 244B may be a ferromagnetic layer, such as HfZrO, HfSiO, or a different ferromagnetic material.

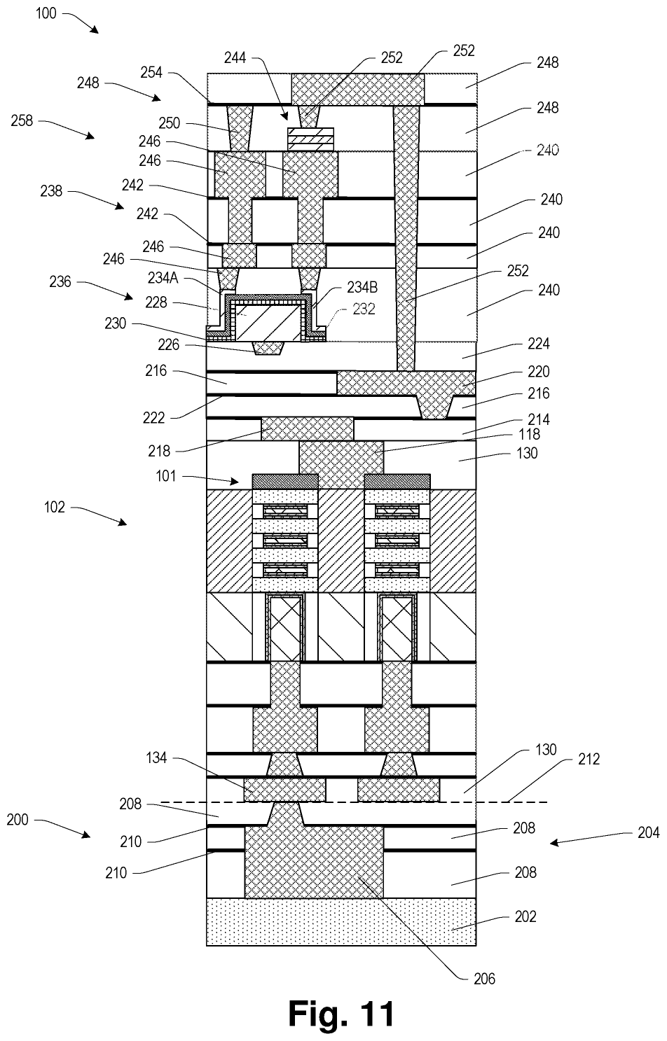

Referring to FIG. 11, metallization layers 248 are formed over the storage element 244, in accordance with some embodiments. In some embodiments, the metallization layers 248 comprise one or more dielectric layers 250 formed over the storage element 244. Any number of dielectric layers 250 are contemplated. In some embodiments, at least one of the dielectric layers 250 comprises a material with a medium or low dielectric constant, such as SiO₂. The dielectric layers 250 are formed in any number of ways, such as by thermal growth, chemical growth, ALD, CVD, PECVD, and/or other suitable techniques. In some embodiments, the semiconductor structure 100 comprises one or more etch stop layers 252 separating the dielectric layers 250. In some embodiments, the etch stop layers 252 stop an etching process between the dielectric layers 250. According to some embodiments, the etch stop layers 252 comprise a dielectric material having a different etch selectivity from the dielectric layers 250. In some embodiments, at least one of the etch stop layers 252 comprises SiN, SiCN, SiCO, and/or CN. The etch stop layers 252 are formed in any number of ways, such as by thermal growth, chemical growth, ALD, CVD, PECVD, and/or other suitable techniques.

In some embodiments, the metallization layers 248 comprise one or more conductive structures 254, 256 electrically connected to the source/drain contacts 234A, 234B. In an embodiment, the conductive structures 254, 256 extend through the respective dielectric layers 130. In some embodiments, at least some of the conductive structures 254, 256 comprise a via portion and a line portion. The line portions are wider than the via portions and have an axial length extending into the page. In some embodiments, the conductive structures 254, 256 comprise a barrier layer, a seed layer, a metal fill layer, and/or other suitable layers. In some embodiments, the metal fill layer comprises tungsten, aluminum, copper, cobalt, and/or other suitable materials. In some embodiments, the conductive structure 256 contacts the second power rail 220.

In some embodiments, the TFT 236, the storage element 244, and interconnections to the second power rail 220 define a memory device 258 formed over the logic device 101. The logic device 101 and the memory device 258 are formed on the device wafer 102, as opposed to bonding a second wafer including memory devices over the device wafer 102.

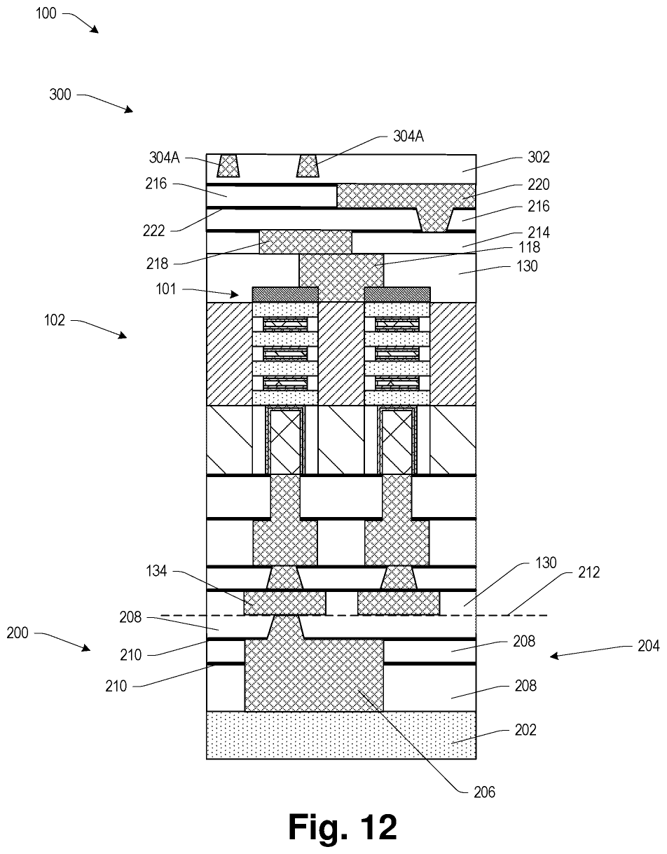

FIGS. 12-16 illustrate the formation of a top gate finFET device 300, in accordance with some embodiments. Referring to FIG. 12, starting with the semiconductor structure of FIG. 3, a dielectric layer 302 is formed over the power rail 220 and the dielectric layer 216, and contacts 304A, 304B are formed in the dielectric layer 302, in accordance with some embodiments. The dielectric layer 302 may comprise a material with a medium or low dielectric constant, such as SiO₂. The dielectric layer 302 is formed in any number of ways, such as by thermal growth, chemical growth, ALD, CVD, PECVD, and/or other suitable techniques. In some embodiments, trenches are formed in the dielectric layer 302, and the trenches are filled with a conductive material and planarized to form the contacts 304A, 304B. In some embodiments, the contacts 304A, 304B comprise a barrier layer, a seed layer, a metal fill layer, and/or other suitable layers. In some embodiments, the metal fill layer comprises tungsten, aluminum, copper, cobalt, and/or other suitable materials.

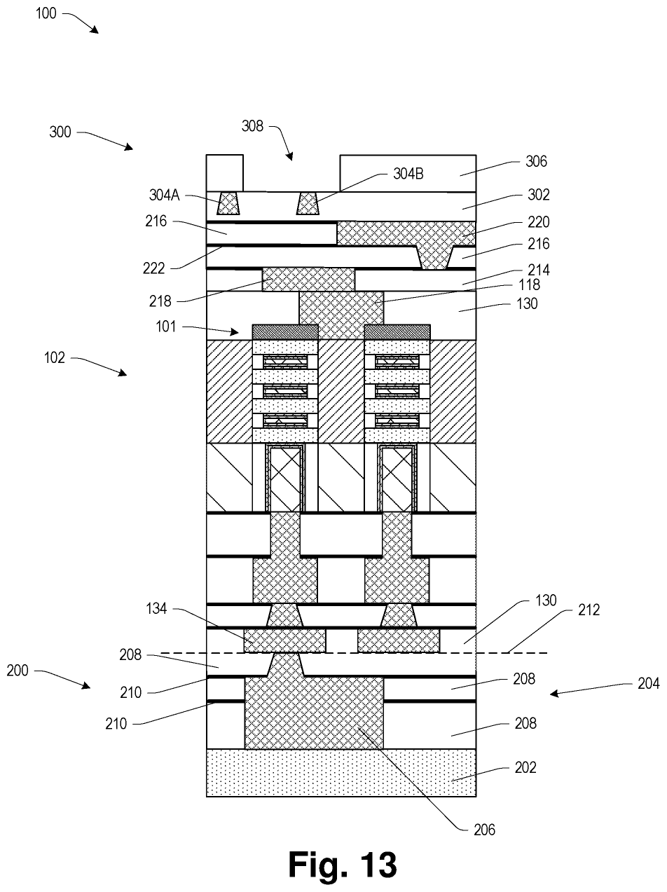

Referring to FIG. 13, a dielectric layer 306 is formed over the dielectric layer 302 and the contacts 304A, 304B, and a trench 308 is formed in the dielectric layer 306, in accordance with some embodiments. The dielectric layer 306 may comprise a material with a medium or low dielectric constant, such as SiO₂. The dielectric layer 306 is formed in any number of ways, such as by thermal growth, chemical growth, ALD, CVD, PECVD, and/or other suitable techniques. The trench 308 is formed by performing an etch process in the presence of a patterned etch mask.

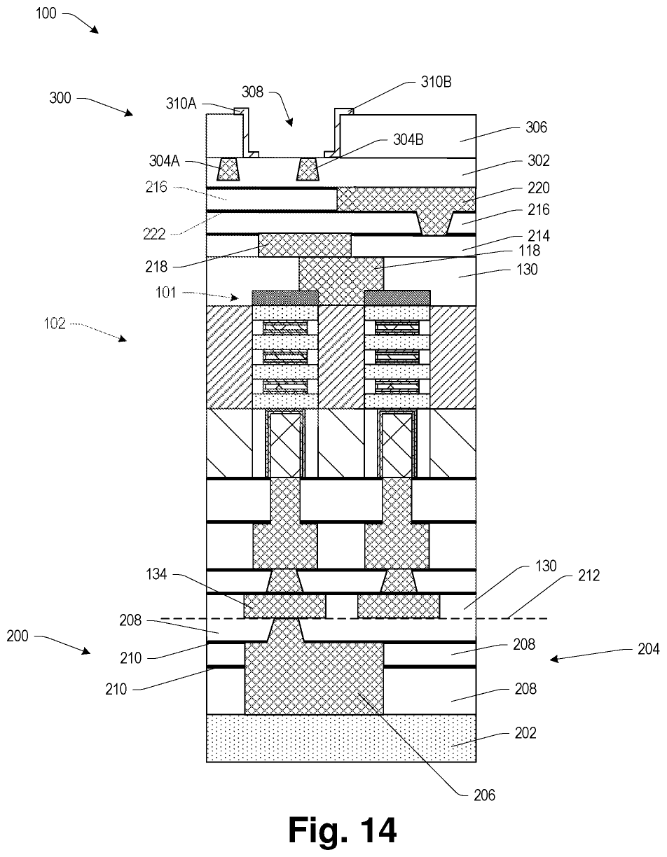

Referring to FIG. 14, a contact layer is formed in the trench 308 and patterned to form source/drain contacts 310A, 310B, in accordance with some embodiments. The contact layer may comprise titanium nitride or other suitable material. The contact layer may be patterned by performing an etch process in the presence of a patterned etch mask.

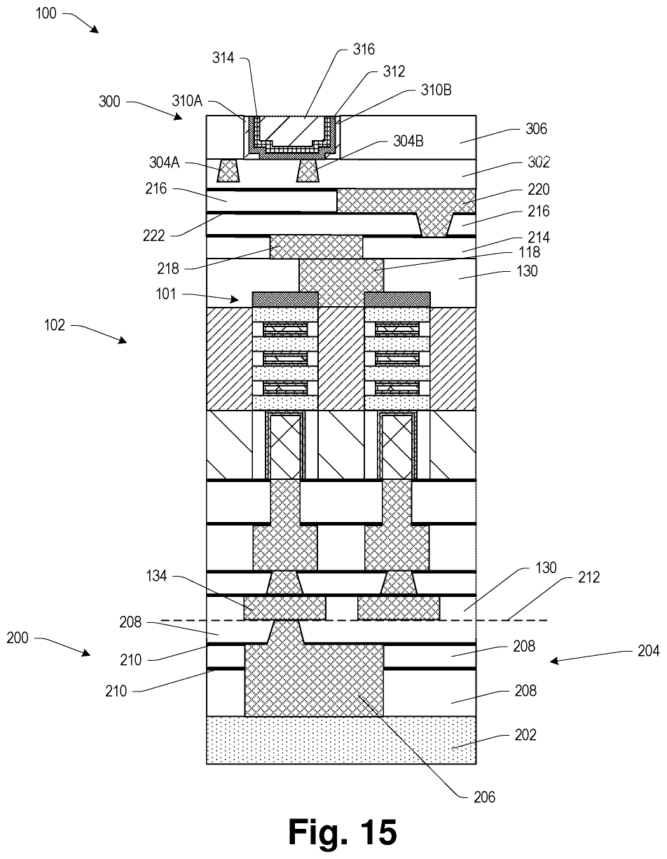

Referring to FIG. 15, a channel layer 312 is formed in the trench 308 over the source/drain contacts 310A, 310B, a gate dielectric layer 314 is formed in the trench 308 over the channel layer 312, a gate electrode 316 is formed over the gate dielectric layer 314 to fill the trench 308, and portions of the channel layer 312, the gate dielectric layer 314, and the gate electrode 316 outside the trench 308 are removed, in accordance with some embodiments. In some embodiments, the channel layer 312 comprises amorphous indium gallium zinc oxide (IGZO). The gate dielectric layer 314 may comprise a high-k dielectric material. The gate electrode 316 may comprise the same material as the source/drain contacts 310A, 310B, such as titanium nitride. The portions of the channel layer 312, the gate dielectric layer 314, and the gate electrode 316 outside the trench 308 may be removed by performing a planarizing process.

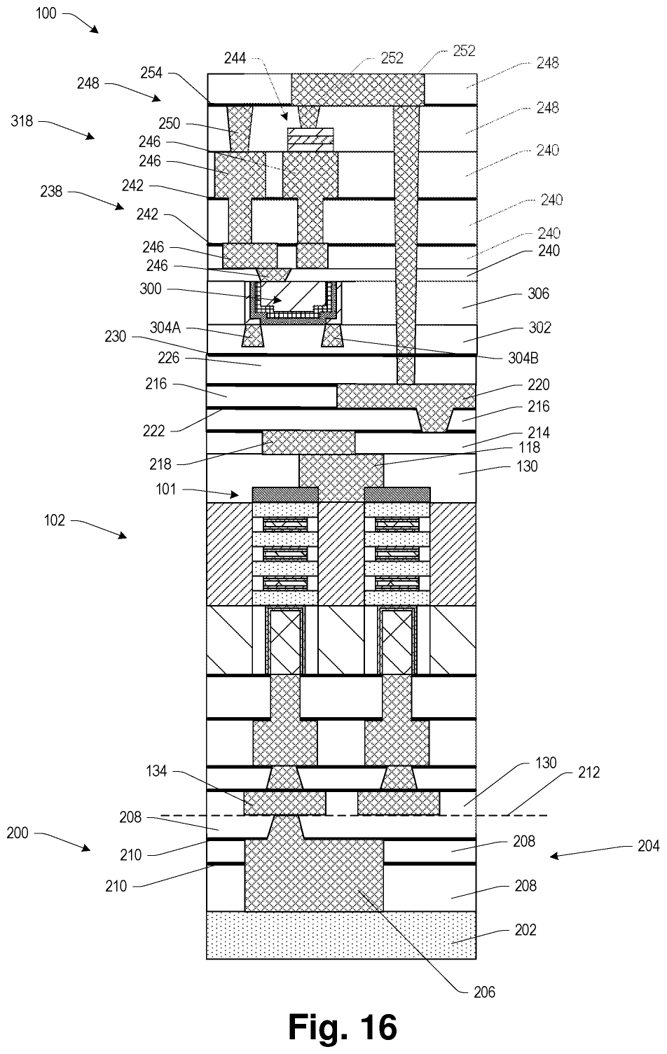

Referring to FIG. 16, the processes of FIGS. 9-11 are repeated to form the metallization layers 238, 248 and the storage element 244, in accordance with some embodiments. In some embodiments, the top gate finFET device 300, the storage element 244, and interconnections to the second power rail 220 define a memory device 318 formed over the logic device 101.

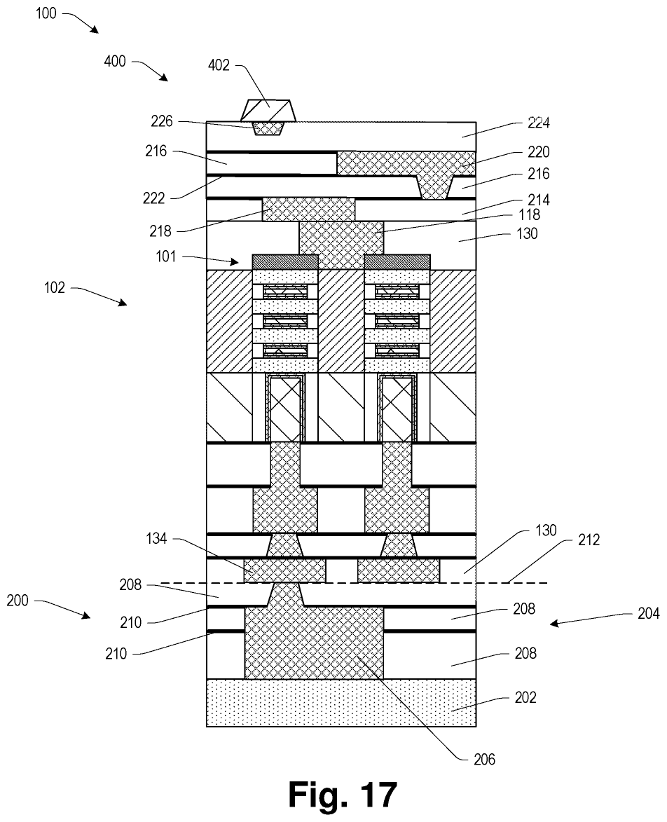

FIGS. 17-20 illustrate the formation of a planar FET device 400, in accordance with some embodiments. Referring to FIG. 17, starting with the semiconductor structure of FIG. 4, a gate electrode 402 is formed over the dielectric layer 224 and the gate contact 226, in accordance with some embodiments. In some embodiments, the gate electrode 402 is formed by depositing a layer of gate electrode material and performing an etch process in the presence of a patterned etch mask. In some embodiments, the gate electrode 402 comprises titanium nitride.

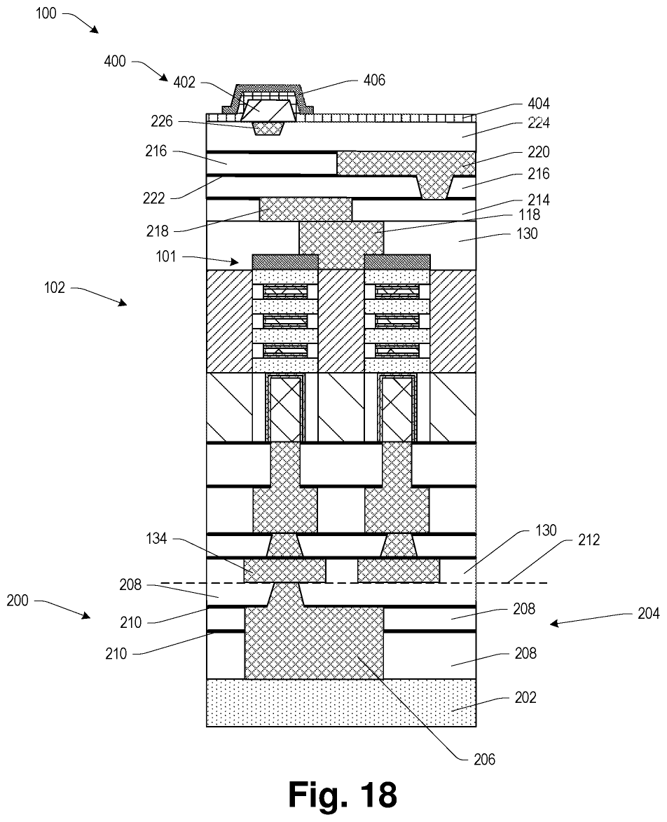

Referring to FIG. 18, a gate dielectric layer 404 and a channel layer 406 are formed over the gate electrode 402, in accordance with some embodiments. The gate dielectric layer 404 may comprise a high-k dielectric material. In some embodiments, the channel layer 406 comprises amorphous indium gallium zinc oxide (IGZO). The channel layer 406 may be patterned by performing an etch process in the presence of a patterned etch mask.

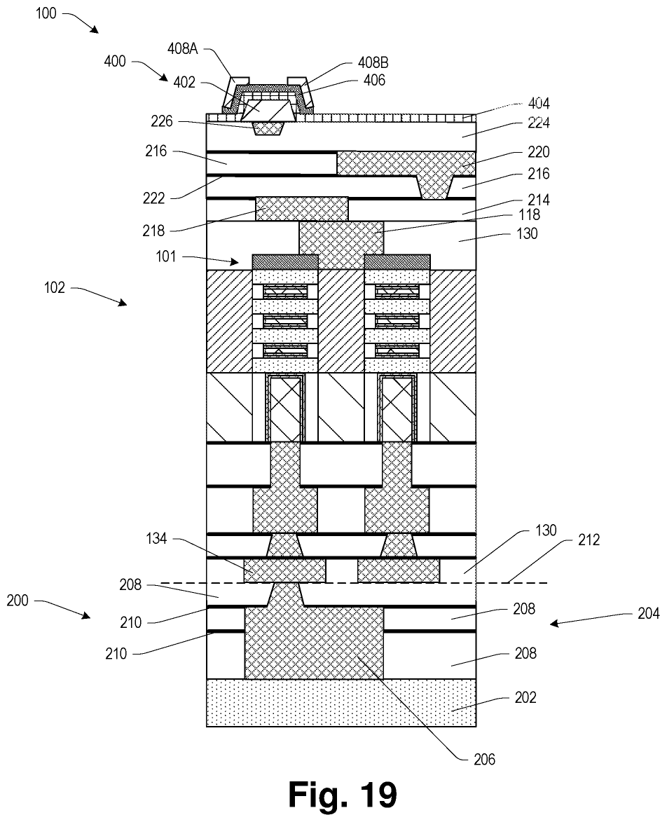

Referring to FIG. 19, a contact layer is formed over the channel layer 406 and patterned to form source/drain contacts 408A, 408B, in accordance with some embodiments. The contact layer may be patterned by performing an etch process in the presence of a patterned etch mask. The source/drain contacts 408A, 408B may comprise the same material as the gate electrode 402, such as titanium nitride.

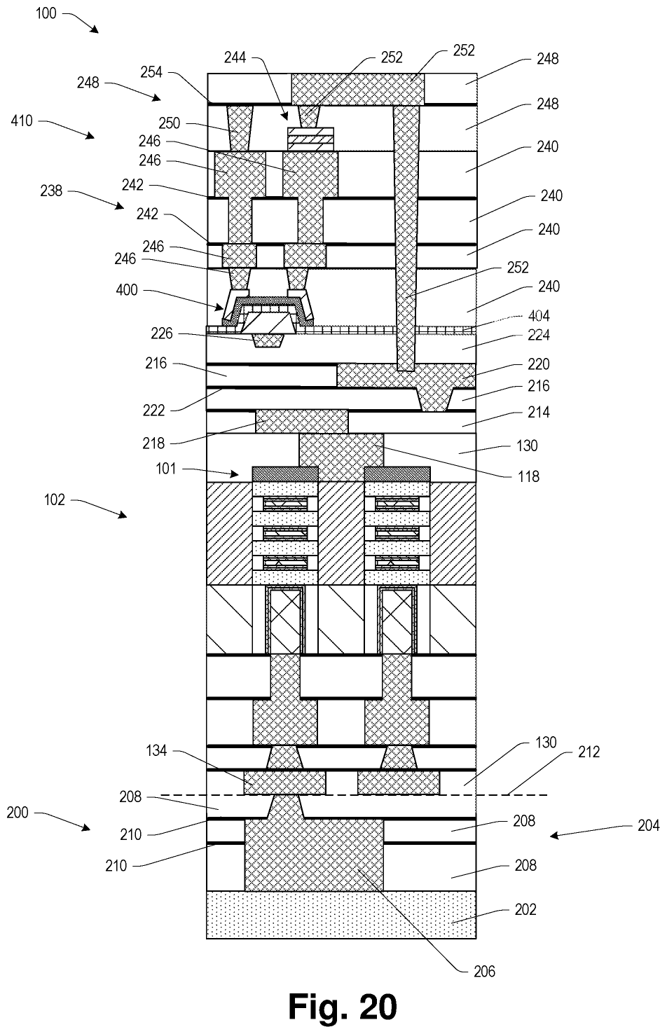

Referring to FIG. 20, the processes of FIGS. 9-11 are repeated to form the metallization layers 238, 248 and the storage element 244, in accordance with some embodiments. In some embodiments, the planar FET device 400, the storage element 244, and interconnections to the second power rail 220 define a memory device 410 formed over the logic device 101.

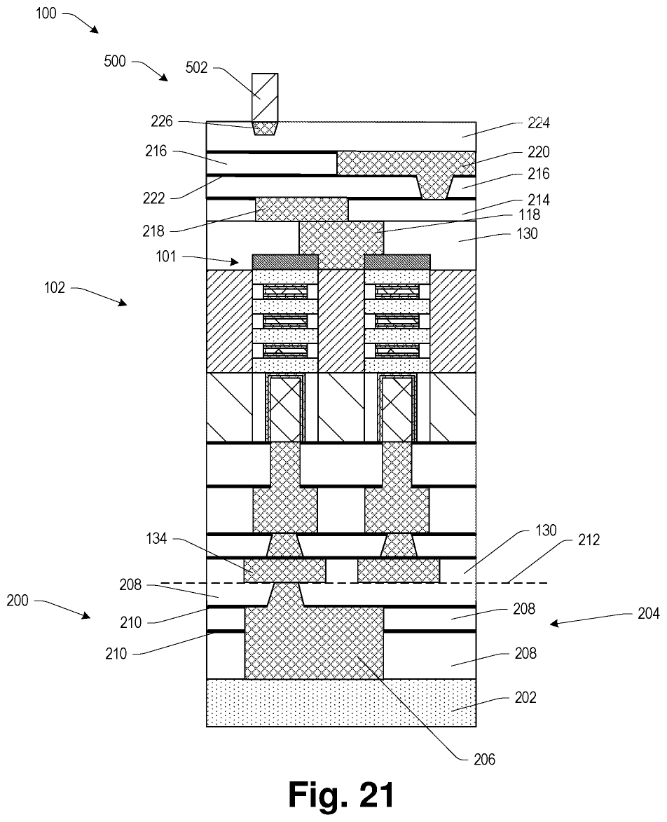

FIGS. 21-26 illustrate the formation of a bottom gate 3D finFET device 500, in accordance with some embodiments. Referring to FIG. 21, starting with the semiconductor structure of FIG. 4, a gate electrode 502 is formed over the dielectric layer 224 and the gate contact 226, in accordance with some embodiments. In some embodiments, the gate electrode 502 is formed by depositing a layer of gate electrode material and performing an etch process in the presence of a patterned etch mask to define a fin. In some embodiments, the gate electrode 502 comprises titanium nitride.

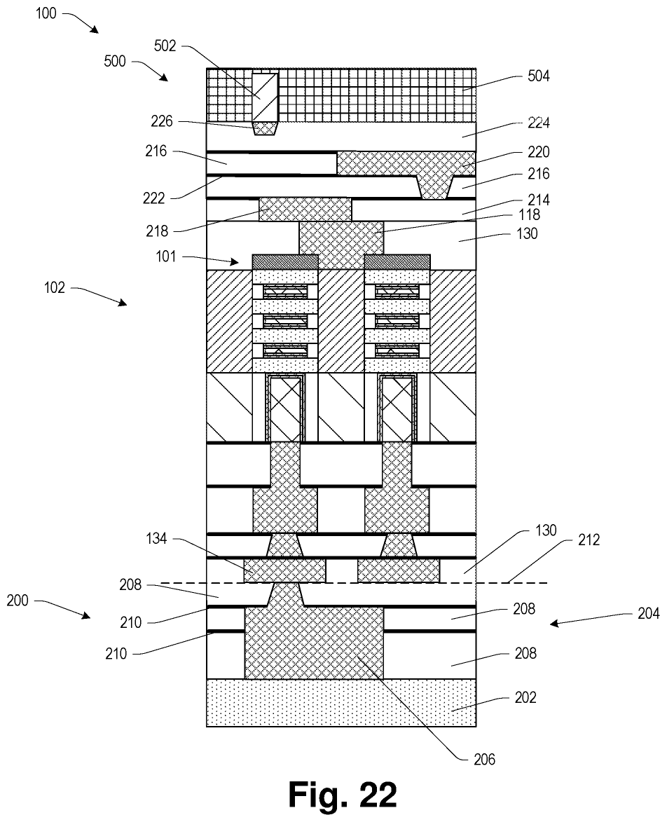

Referring to FIG. 22, a gate dielectric layer 504 is formed over the gate electrode 502, in accordance with some embodiments. The gate dielectric layer 504 may comprise a high-k dielectric material.

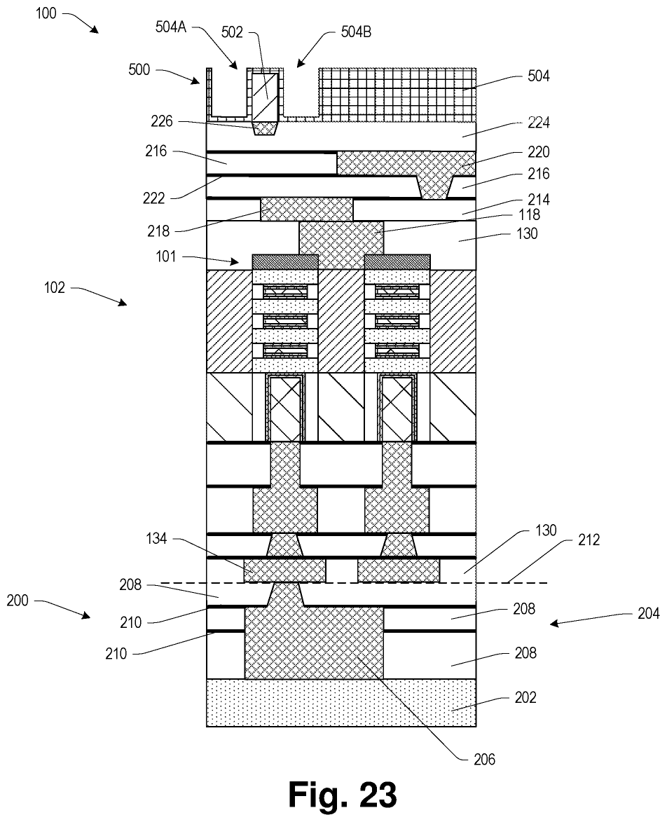

Referring to FIG. 23, trenches 504A, 504B are formed in the gate dielectric layer 504, in accordance with some embodiments. The trenches 504A, 504B may be formed by performing an etch process in the presence of a patterned etch mask.

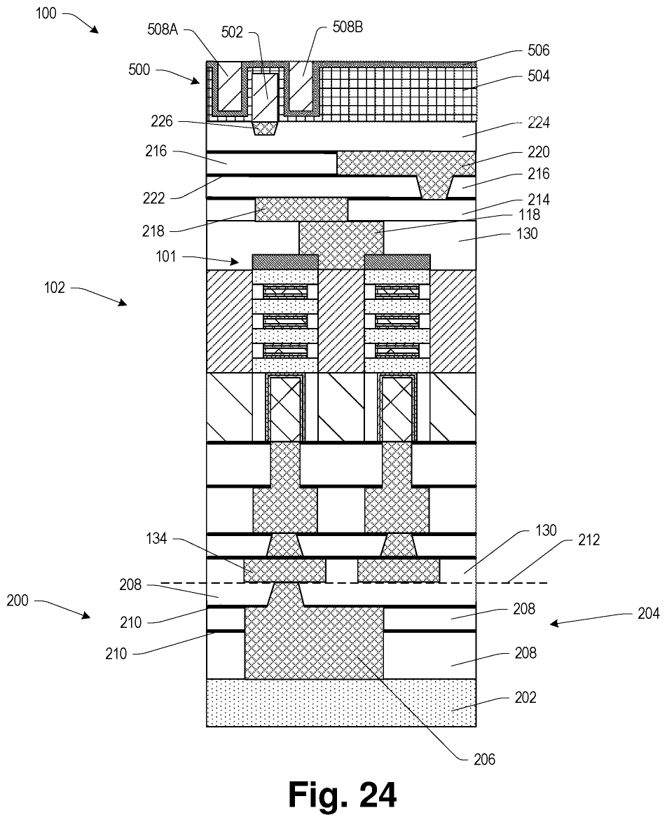

Referring to FIG. 24, a channel layer 506 is formed in the trenches 504A, 504B, and source/drain contacts 508A, 508B are formed over the channel layer 506 to fill the trenches 504A, 504B, in accordance with some embodiments. In some embodiments, the channel layer 506 comprises amorphous indium gallium zinc oxide (IGZO). In some embodiments, a planarization process is performed to remove portions of the source/drain contacts 508A, 508B outside the trenches 504A, 504B. The source/drain contacts 508A, 508B may comprise the same material as the gate electrode 502, such as titanium nitride.

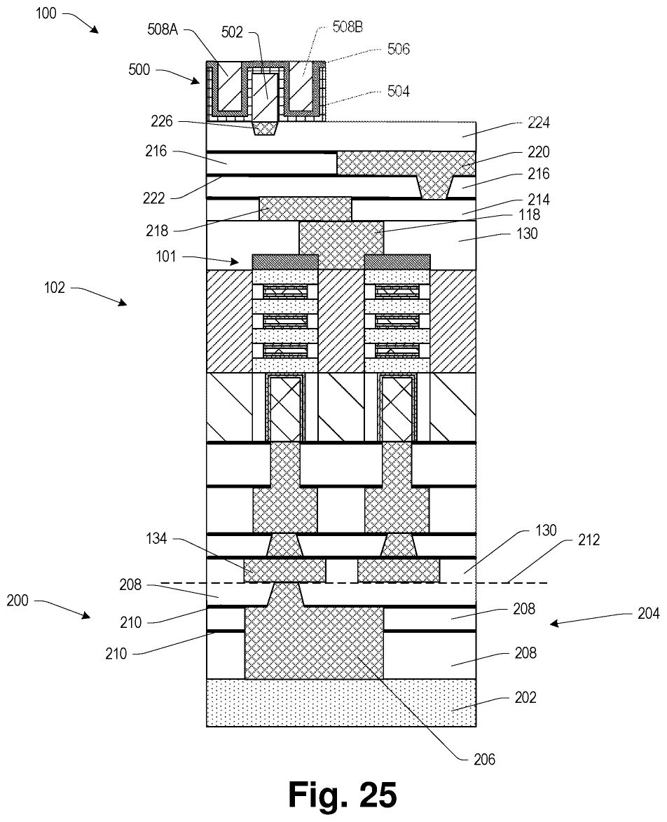

Referring to FIG. 25, portions of the gate dielectric layer 504 and the channel layer 506 are removed, in accordance with some embodiments. The portions of the gate dielectric layer 504 and the channel layer 506 may be removed by performing an etch process in the presence of a patterned etch mask.

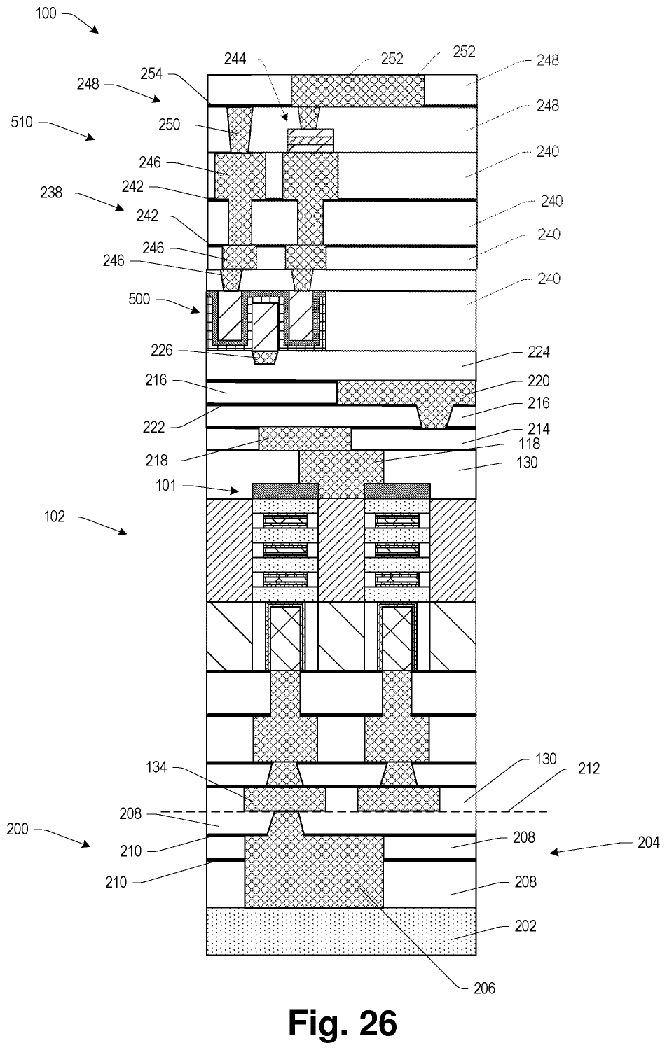

Referring to FIG. 26, the processes of FIGS. 9-11 are repeated to form the metallization layers 238, 248 and the storage element 244, in accordance with some embodiments. In some embodiments, the bottom gate 3D finFET device 500, the storage element 244, and interconnections to the second power rail 220 define a memory device 510 formed over the logic device 101.

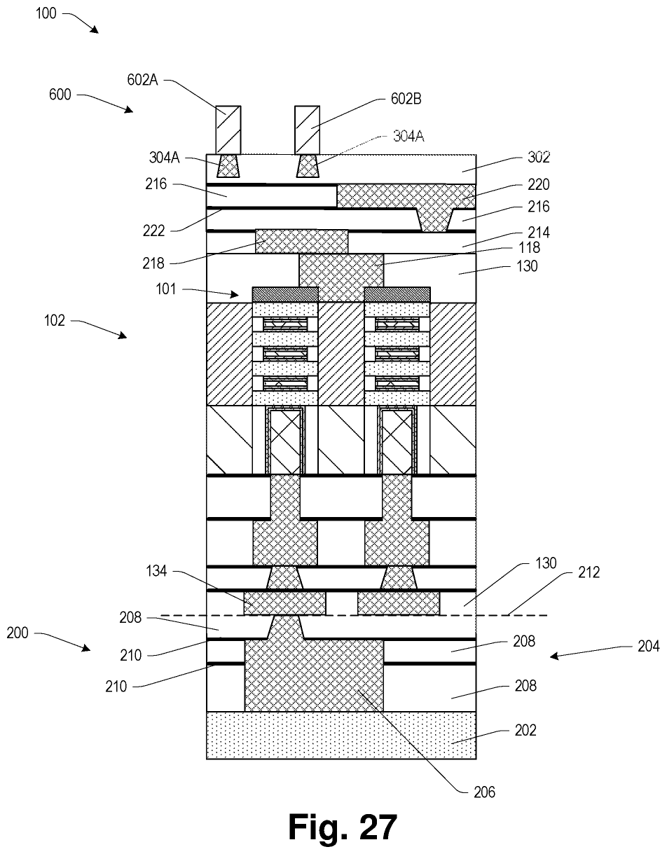

FIGS. 27-30 illustrate the formation of a top gate 3D finFET device 600, in accordance with some embodiments. Referring to FIG. 27, starting with the semiconductor structure of FIG. 12, source/drain contacts 602A, 602B are formed over the dielectric layer 302 and the contacts 304A, 304B, in accordance with some embodiments. In some embodiments, the source/drain contacts 602A, 602B are formed by depositing a layer of contact material and performing an etch process in the presence of a patterned etch mask to define fins. In some embodiments, the source/drain contacts 602A, 602B comprise titanium nitride.

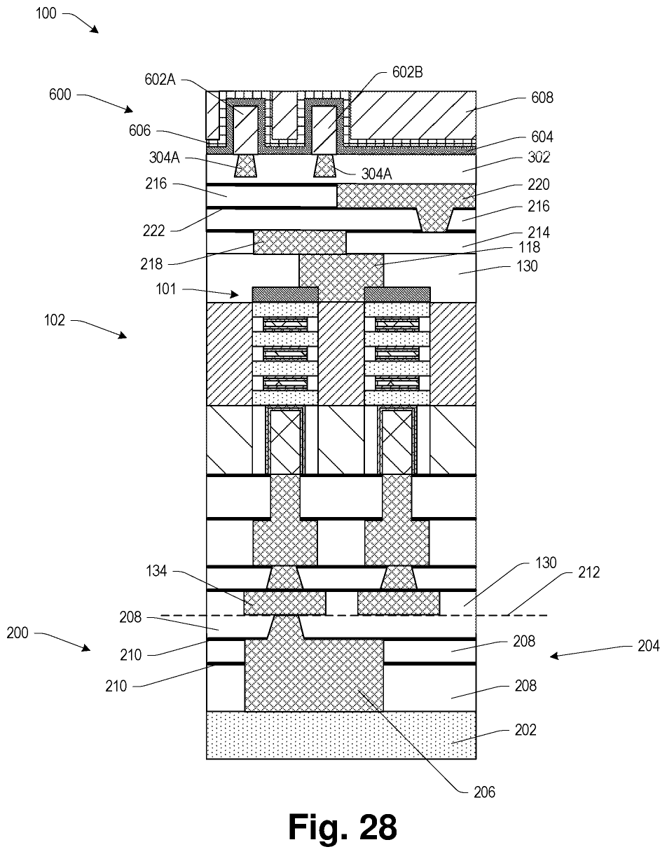

Referring to FIG. 28, a channel layer 604 is formed over the source/drain contacts 602A, 602B, a gate dielectric layer 606 is formed over the channel layer 604, a gate electrode layer 608 is formed over the gate dielectric layer 606, and the gate electrode layer 608 is planarized, in accordance with some embodiments. In some embodiments, the channel layer 604 comprises amorphous indium gallium zinc oxide (IGZO). The gate dielectric layer 606 may comprise a high-k dielectric material. The gate electrode layer 608 may comprise the same material as the source/drain contacts 602A, 602B, such as titanium nitride.

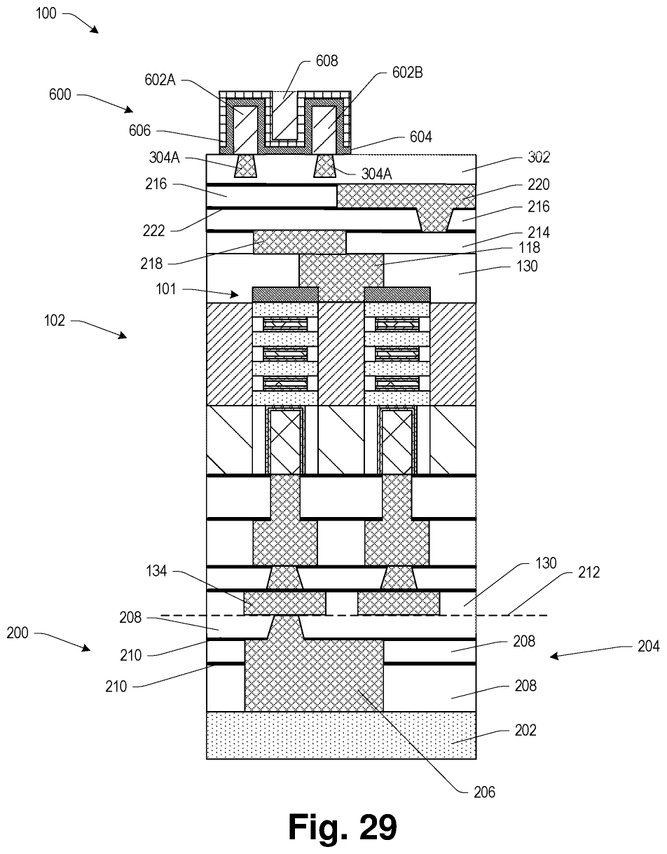

Referring to FIG. 29, portions of the channel layer 604, the gate dielectric layer 606, and the gate electrode layer 608 are removed, in accordance with some embodiments. The portions of the channel layer 604, the gate dielectric layer 606, and the gate electrode layer 608 may be removed by performing an etch process in the presence of a patterned etch mask.

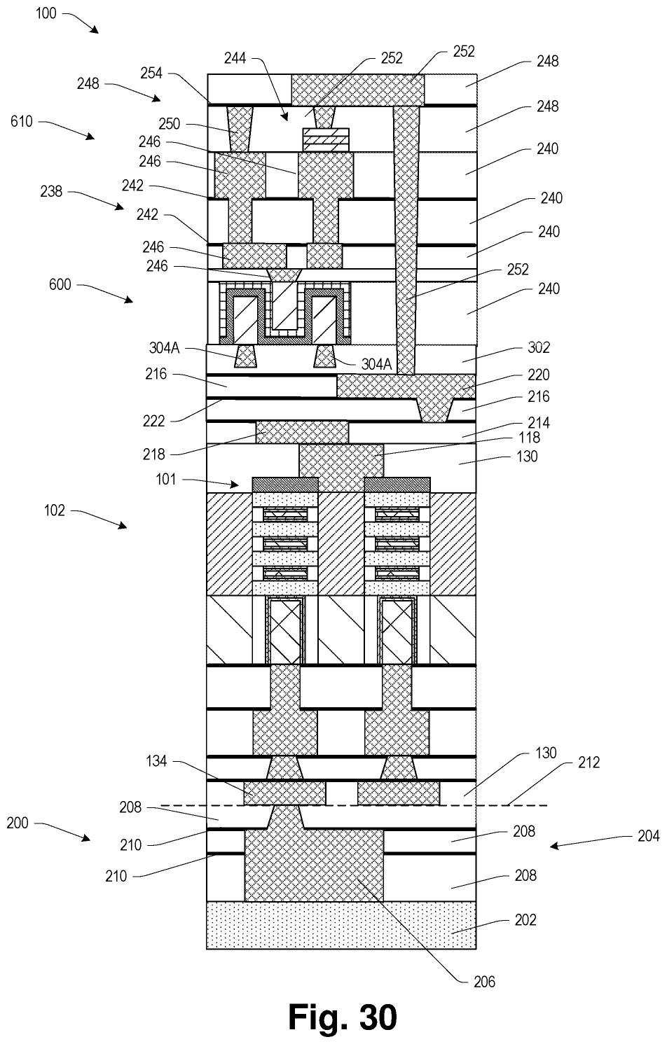

Referring to FIG. 30, the processes of FIGS. 9-11 are repeated to form the metallization layers 238, 248 and the storage element 244, in accordance with some embodiments. In some embodiments, the top gate 3D finFET device 600, the storage element 244, and interconnections to the second power rail 220 define a memory device 610 formed over the logic device 101.

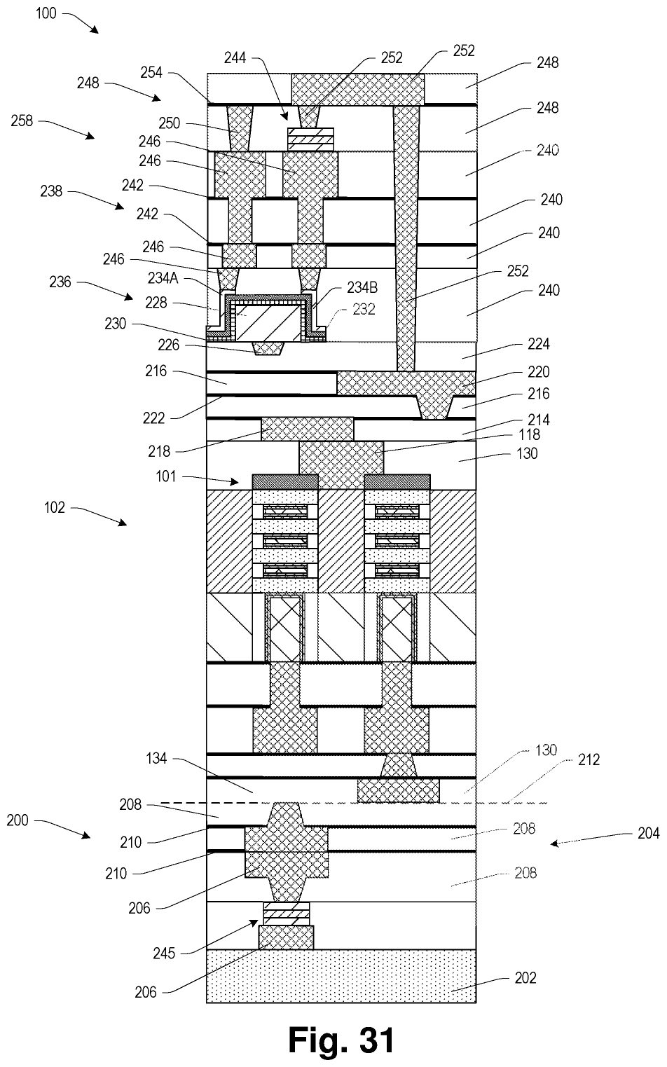

Referring to FIG. 31, the semiconductor structure 100 of FIG. 12 is shown with a second storage element 245 formed in the carrier wafer 200, in accordance with some embodiments. In some embodiments, the second storage element 244B has the same configuration as the storage element 244. The metallization layer 204 of the carrier wafer 200 may have a different configuration to provide interconnections between the second storage element 245 and the logic devices 101. The second storage element 245 may be provided in any of the embodiments of FIG. 16, 20, 26, or 30.

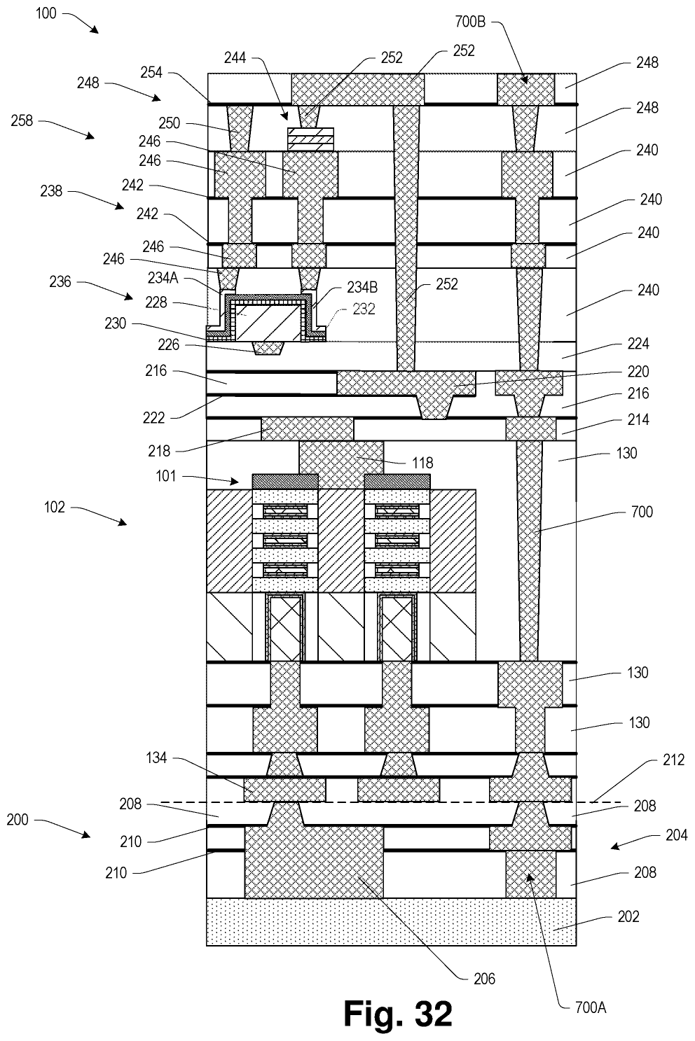

Referring to FIG. 32, the semiconductor structure 100 of FIG. 12 is shown with a seal ring 700 adjacent the memory device 258 and the logic devices 101, in accordance with some embodiments. The seal ring 700 may comprise a first portion 700A in the carrier wafer 200 that connects to a second portion 700B in the device wafer 102. The seal ring 700 may be made in parallel with the various metallization layers. The seal ring 700 may comprise a barrier layer, a seed layer, and a fill layer, such as copper. The seal ring 700 may be provided in any of the embodiments of FIG. 16, 20, 26, 30, or 31.

The use of an IGZO material for the channel layer of the transistors 238, 300, 400, 500, 600 in the memory devices 258, 318, 410, 510, 610 obviates the need for a dopant activating anneal, thereby providing a low thermal budget process that is suitable for BEOL processing. The memory devices may be devices such as resistive random access memory (RRAM) devices, dynamic random access memory (DRAM) devices, magnetic random access memory (MRAM) devices, ferromagnetic random access memory (FeRAM) devices, or some other memory technology. The use of hybrid bonding with conductive structures in the carrier wafer 200 improves heat transfer, and potentially performance. Double sided memory may be provided by including additional memory devices in the carrier wafer 200.

A semiconductor structure includes a logic device, a first contact connected to the logic device, a first power rail over the logic device and connected to the logic device, and a second power rail over the logic device. A transistor having a channel region including indium, gallium, zinc, and oxygen is over the second power rail and connected to the second power rail.

A method for forming a semiconductor structure includes forming a logic device on a device wafer, inverting the device wafer, forming a backside contact connected to the logic device, forming a first power rail connected to the backside contact, forming a second power rail, and forming a memory device over the second power rail. Forming the memory device includes forming a transistor having a channel layer comprises indium, gallium, zinc, and oxygen, forming a first storage element connected to the transistor, and connecting the second power rail to the memory device.

A semiconductor structure includes a carrier wafer and a device wafer. The carrier wafer includes a substrate layer, a first dielectric layer, and a first conductive structure embedded in the first dielectric layer. The device wafer includes a logic device connected to the first conductive structure, a backside contact connected to the logic device, and a second dielectric layer under the logic device and bonded to the first dielectric layer of the carrier wafer. A third dielectric layer is over the logic device and a first power rail is embedded in the third dielectric layer and connected to the logic device. A fourth dielectric layer is over the logic device and a second power rail is embedded in the fourth dielectric layer. A memory device is over the second power rail and connected to the second power rail. The memory device includes a transistor having a channel layer including indium, gallium, zinc, and oxygen.

The foregoing outlines features of several embodiments so that those of ordinary skill in the art may better understand various aspects of the present disclosure. Those of ordinary skill in the art should appreciate that they may readily use the present disclosure as a basis for designing or modifying other processes and structures for carrying out the same purposes and/or achieving the same advantages of various embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A semiconductor structure, comprising:
a logic device;
a first contact connected to the logic device;
a first power rail over the logic device and connected to the logic device;
a second power rail over the logic device; and
a transistor having a channel region comprising indium, gallium, zinc, and oxygen over the second power rail and connected to the second power rail.

2. The semiconductor structure of claim 1, comprising:
a first storage element connected between the second power rail and the transistor.

3. The semiconductor structure of claim 2, wherein the first storage element comprises:
a first conductive layer;
an insulator layer over the first conductive layer; and
a second conductive layer over the insulator layer.

4. The semiconductor structure of claim 2, wherein:
the first storage element comprises at least one of a resistive random access memory storage element, a dynamic random access memory storage element, a magnetic random access memory storage element, or a ferromagnetic random access memory storage element.

5. The semiconductor structure of claim 1, wherein:
the transistor comprises at least one of a bottom gate fin field effect transistor (finFET) device, a top gate finFET device, or a planar device.

6. The semiconductor structure of claim 1, comprising:
a seal ring adjacent the logic device and the transistor.

7. The semiconductor structure of claim 1, comprising:
a second storage element under the logic device.

8. A method for forming a semiconductor structure, comprising:
forming a logic device on a device wafer;
inverting the device wafer;
forming a backside contact connected to the logic device;
forming a first power rail connected to the backside contact;
forming a second power rail; and
forming a memory device over the second power rail, wherein forming the memory device comprises:
forming a transistor having a channel layer comprising indium, gallium, zinc, and oxygen;
forming a first storage element connected to the transistor; and
connecting the second power rail to the memory device.

9. The method of claim 8, wherein:
forming the logic device comprise forming the logic device on a device wafer,
the method comprises:
bonding a carrier wafer to the device wafer, and
forming the memory device comprises forming the memory device on the device wafer after bonding the carrier wafer to the device wafer.

10. The method of claim 9, wherein bonding the carrier wafer to the device wafer comprises:
bonding a first dielectric layer in the carrier wafer to a second dielectric layer in the device wafer; and
bonding a first conductive structure embedded in the first dielectric layer to a second conductive structure embedded in the second dielectric layer.

11. The method of claim 9, comprising:
forming a second storage element in the carrier wafer prior to bonding the carrier wafer to the device wafer.

12. The method of claim 9, comprising:
forming a seal ring adjacent the logic device and the memory device, wherein:
a first portion of the seal ring is in the carrier wafer, and
a second portion of the seal ring is in the device wafer.

13. The method of claim 8, wherein forming the first storage element comprises:
forming a first conductive layer;
forming an insulator layer over the first conductive layer; and
forming a second conductive layer over the insulator layer.

14. The method of claim 13, wherein forming the insulator layer comprises:
forming at least one of a dielectric material, a resistive material, or a ferromagnetic material.

15. The method of claim 13, wherein at least one of forming the first conductive layer or forming the second conductive layer comprises:
forming a ferromagnetic material.

16. A semiconductor structure, comprising:
a carrier wafer comprising:
a substrate layer;
a first dielectric layer; and
a first conductive structure embedded in the first dielectric layer; and
a device wafer comprising:
a logic device connected to the first conductive structure;
a backside contact connected to the logic device;
a second dielectric layer under the logic device and bonded to the first dielectric layer of the carrier wafer;
a third dielectric layer over the logic device;
a first power rail embedded in the third dielectric layer and connected to the logic device;
a fourth dielectric layer over the logic device;
a second power rail embedded in the fourth dielectric layer; and
a memory device over the second power rail and connected to the second power rail, wherein the memory device comprises a transistor having a channel layer comprising indium, gallium, zinc, and oxygen.

17. The semiconductor structure of claim 16, wherein the memory device comprises:
a first storage element connected between the second power rail and the transistor.

18. The semiconductor structure of claim 17, wherein the first storage element comprises:
a first conductive layer;
an insulator layer over the first conductive layer; and
a second conductive layer over the insulator layer.

19. The semiconductor structure of claim 16, wherein the carrier wafer comprises:
a second storage element.

20. The semiconductor structure of claim 16, comprising:
a seal ring adjacent the logic device and the memory device, wherein:
a first portion of the seal ring is in the carrier wafer, and
a second portion of the seal ring is in the device wafer.
